(19) United States
(12) Patent Application Publication
(10) Pub. No.: US 2025/0211291 A1
(43) Pub. Date: Jun. 26, 2025

(54) SYSTEM AND METHOD FOR TELECOMMUNICATION NETWORK

(71) Applicant: Samsung Electronics Co., Ltd., Suwon-si (KR)

(72) Inventors: Mutasem HAMDAN, Staines (GB); Joan PUJOL-ROIG, Staines (GB); Junhyuk SONG, Suwon-si (KR); Yue WANG, Staines (GB)

(21) Appl. No.: 19/076,628

(22) Filed: Mar. 11, 2025

Related U.S. Application Data
(63) Continuation of application No. PCT/KR2024/013531, filed on Sep. 6, 2024.

(30) Foreign Application Priority Data
Sep. 8, 2023 (GB) 2313737.5
Aug. 8, 2024 (GB) 2411730.1

(51) Int. Cl. H04B 7/0426; H04B 7/0456; H04L 67/00

(52) U.S. Cl. CPC H04B 7/043; H04B 7/0456; H04L 67/34

(57) ABSTRACT

According to an embodiment, a method performed by a device for a near-real time radio access network intelligent controller, (near-RT RIC) of a telecommunication network, wherein the method comprises generating a control message for configuration related to at least one function of a radio unit (RU), and transmitting, to the RU, the control message via an interface between the near-RT RIC and the RU.

### CROSS-REFERENCE TO RELATED APPLICATION(S)

This application is a continuation application, claiming priority under 35 U.S.C. § 365 (c), of an International application No. PCT/KR2024/013531, filed on Sep. 6, 2024, which is based on and claims the benefit of a United Kingdom patent application number 2313737.5, filed on Sep. 8, 2023, in the United Kingdom Intellectual Property Office, and of a United Kingdom patent application number 2411730.1, filed on Aug. 8, 2024, in the United Kingdom Intellectual Property Office, the disclosures of each of which is incorporated by reference herein in its entirety.

### BACKGROUND

### 1. Field

The present disclosure relates to an improved service model for use in a telecommunication network. It finds particular, but not exclusive, utility in a Sixth Generation (6G) Open Radio Access Network (O-RAN) network, but other systems can benefit from an embodiment of the disclosure.

### 2. Description of Related Art

Open and disaggregated network structure has become a main feature and technology trend within a 6G network. In particular, the concept of open radio access network (Open RAN) enables a more open and disaggregated radio access network architecture to improve network flexibility, and avoid vendor lock-in. In order to encourage the development of a non-fragmented Open RAN system, the O-RAN alliance organisation has developed an O-RAN architecture, that enables the building of the virtualised RAN on open hardware and cloud platform, with embedded Artificial Intelligence (AI) powered radio control. In particular, xApps/rApps can be developed to configure E2 nodes (including Central Unit (CU) and Distributed Unit (DU)) using AI, through interfaces such as O1 and A1.

A high level architecture used in O-RAN is shown in FIG. 1, which shows an open radio access network (O-RAN) including radio units (RU), digital units (DU), control units (CU)-control plane (CP), and user planes (UP) as O (O-RAN)-RU, O-DU, O-CU-CP, O-CU-UP.

RAN Intelligent Controller (RIC) is a software-defined component of the Open Radio Access Network (Open RAN) architecture that's responsible for controlling and optimizing RAN functions.

RIC is a logical node that can collect information on cell sites transmitted and received by a User Equipment (UE), O-eNB, O-DU, O-CU-CP, or O-CU-UP. The RIC can be implemented in the form of a server concentrated in one physical place or it can be implemented as a logical function within the Base Station (gNB). In the following, the nodes that are connected to RIC through the E2 interface, are referred to as E2 nodes. It is understood that embodiments of the disclosure may generally be applied to E2 nodes, regardless of what the E2 nodes are. Here, E2 nodes may be understood as objects constituting a RAN that can operate according to the O-RAN standard, and may be referred to as an E2 node. An E2 node may also refer to an O-eNB.

xApps can be developed in the Near-RT RIC and provide control to the RAN functions in the E2 nodes.

The above information is presented as background information only to assist with an understanding of the disclosure. No determination has been made, and no assertion is made, as to whether any of the above might be applicable as prior art with regard to the disclosure.

### SUMMARY

rApps can developed in Non-RT RIC as a platform application that provides analytics related function and RAN governing policy function.

Currently, the configuration of O-RU is performed through the O1 interface, however, there is no direct interface between xApps/rApps and O-RU, so that O-RU can be intelligently configured effectively. A 6G network is expected to be capable of configuring O-RU parameters automatically. Embodiments of the disclosure provide a new RU service model that will enable the intelligent configuration of O-RU via xApps and rApps in near-RT RIC and non-RT RIC. In particular, embodiments of the disclosure provide apparatus, methods, functions and interfaces based on an O-RAN architecture, to enable intelligent control of O-RU in O-RAN.

It is an aim of an embodiment of the present disclosure to address issues in the prior art, whether mentioned herein or not.

According to the present disclosure there is provided an apparatus and method as set forth in the appended claims. Other features of the disclosure will be apparent from the dependent claims, and the description which follows.

According to a first aspect of the present disclosure, there is provided a method of operating a telecommunication network, the network comprising at least one Radio Unit, O-RU, node and at least one intelligent system in an Open-Radio Access Network, O-RAN, architecture, comprising the step of configuring the at least one RU node by means of at least one of a near-real-time RAN Intelligent Controller, RIC, and a non-real-time RIC.

In an embodiment, an xApp is provided in the near-real-time RIC or an rApp is provided in the non-real-time RIC.

In an embodiment, an Artificial Intelligence/Machine Learning, AI/ML, model is deployed as or within an xApp instance

In an embodiment, the AI/ML model is arranged to be updated via an xApp software update.

In an embodiment, an AI/ML model is decoupled from an xApp and is arranged to be enabled or updated via an xApp file configuration.

In an embodiment, an O-RAN Network Function, NF, is arranged to be managed via an O1 interface and an authorised service orchestration and management, SMO, framework and, additionally, a further interface is provided whereby the O-RU functionality may be controlled directly from near-real-time RIC.

In an embodiment, a control model is provided which allows the configuration of the O-RU according to actions from the xApp or rApp.

In an embodiment, an interface is provided between the O-RU and one or more of the near-real-time RIC and the non-real-time RIC, wherein the interface comprises at least one of: a list of IDs of certain O-RU components to be configured; and certain parameters of the O-RU to be configured.

In an embodiment, the certain parameters comprise one or more of antenna tilt and ADC quantisation level.

In an embodiment, the interface is arranged to acknowledge completion of actions from the O-RU to the near-real-time RIC or the non-real-time RIC.

In an embodiment, the O-RU is arranged to report update of parameters after an action is taken.

According to a second aspect of the present disclosure, there is provided as apparatus arranged to perform the method of the first aspect.

Although a few preferred embodiments of the present disclosure have been shown and described, it will be appreciated by those skilled in the art that various changes and modifications might be made without departing from the scope of the disclosure, as defined in the appended claims.

### BRIEF DESCRIPTION OF THE DRAWINGS

For a better understanding of the disclosure, and to show how embodiments of the same may be carried into effect, reference will now be made, by way of example only, to the accompanying diagrammatic drawings in which:

FIG. 1 shows an O-RAN high level architecture;

FIG. 2 shows interfaces to enable near-RT RIC control of O-RU according to an embodiment of the disclosure;

FIG. 3 shows interfaces to enable Non-RT RIC control of O-RU according to an embodiment of the disclosure;

FIG. 4 shows interfaces to enable both Non-RT RIC and near-RT RIC control of O-RU according to an embodiment of the disclosure;

FIG. 5 shows O-RU xApp-high level architecture according to an embodiment of the disclosure;

FIG. 6A shows a prior art configuration;

FIG. 6B shows a means of enabling direct configuration of O-RU by near-RT RIC according to an embodiment of the disclosure;

FIG. 7A shows a prior art configuration;

FIG. 7B shows a means of enabling direct configuration of O-RU by non-RT RIC according to an embodiment of the disclosure;

FIG. 8A shows a representation of O-RU control CONTROL service style direct control mode RIC according to an embodiment of the disclosure;

FIG. 8B shows a representation of O-RU control CONTROL service style Hierarchy mode according to an embodiment of the disclosure;

FIG. 9 shows xApps and RU functions according to an embodiment of the disclosure;

FIG. 10 shows an example of PA requirements for O-RU interfaces to collect data, monitor PA performance and allow real time control and configuration according to an embodiment of the disclosure;

FIG. 11 shows an example of Precoding parameters using an interface for O-RU according to an embodiment of the disclosure;

FIG. 12 shows a procedure example to configure PA(s) of O-RU using an interface according to an embodiment of the disclosure;

FIG. 13 shows a procedure example to configure Precoder(s) of O-RU using an interface according to an embodiment of the disclosure;

FIG. 14 illustrates a fronthaul interface according to an embodiment of the disclosure;

FIG. 15A illustrates a functional configuration of a distributed unit (DU) according to an embodiment of the disclosure; and

FIG. 15B illustrates a functional configuration of a radio unit (RU) according to an embodiment of the disclosure.

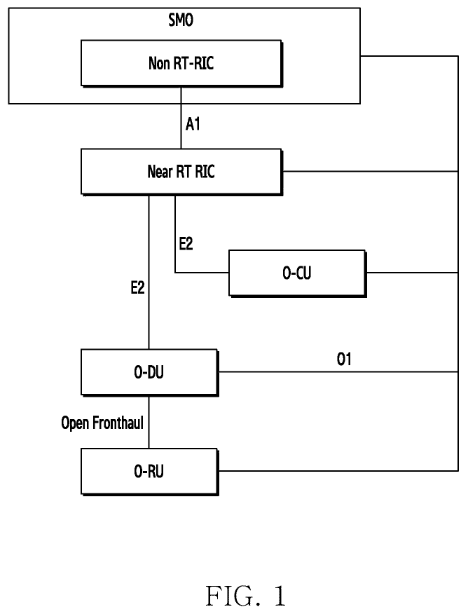

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope of the disclosure. In addition, descriptions of well-known functions and constructions may be omitted for clarity and conciseness.

The terms and words used in the following description and claims are not be limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In various examples of the disclosure described below, a hardware approach will be described as an example. However, since various embodiments of the disclosure may include a technology that utilizes both the hardware-based and the software-based approaches, they are not intended to exclude the software-based approach.

As used herein, the terms referring to merging (e.g., merging, grouping, combination, aggregation, joint, integration, unifying), the terms referring to signals (e.g., packet, message, signal, information, signaling), the terms referring to resources (e.g. section, symbol, slot, subframe, radio frame, subcarrier, resource element (RE), resource block (RB), bandwidth part (BWP), opportunity), the terms used to refer to any operation state (e.g., step, operation, procedure), the terms referring to data (e.g. packet, message, user stream, information, bit, symbol, codeword), the terms referring to a channel, the terms referring to a network entity (e.g., distributed unit (DU), radio unit (RU), central unit (CU), control plane (CU-CP), user plane (CU-UP), O-DU-open radio access network (O-RAN) DU), O-RU (O-RAN RU), O-CU (O-RAN CU), O-CU-UP (O-RAN CU-CP), O-CU-CP (O-RAN CU-CP)), the terms referring to the components of an apparatus or device, or the like are only illustrated for convenience of description in the disclosure. Therefore, the disclosure is not limited to those terms described below, and other terms having the same or equivalent technical meaning may be used therefor. Further, as used herein, the terms, such as ‘˜ module’, ‘˜ unit’, ‘˜ part’, ‘˜ body’, or the like may refer to at least one shape of structure or a unit for processing a certain function.

Further, throughout the disclosure, an expression, such as e.g., ‘above’ or ‘below’ may be used to determine whether a specific condition is satisfied or fulfilled, but it is merely of a description for expressing an example and is not intended to exclude the meaning of ‘more than or equal to’ or ‘less than or equal to’. A condition described as ‘more than or equal to’ may be replaced with an expression, such as ‘above’, a condition described as ‘less than or equal to’ may be replaced with an expression, such as ‘below’, and a condition described as ‘more than or equal to and below’ may be replaced with ‘above and less than or equal to’, respectively. Furthermore, hereinafter, ‘A’ to ‘B’ means at least one of the elements from A (including A) to B (including B). Hereinafter, ‘C’ and/or ‘D’ means including at least one of ‘C’ or ‘D’, that is, {′C′, ‘D’, or ‘C’ and ‘D’}.

The disclosure describes various embodiments using terms used in some communication standards (e.g., 3rd Generation Partnership Project (3GPP), extensible radio access network (xRAN), open-radio access network (O-RAN) or the like), but it is only of an example for explanation, and the various embodiments of the disclosure may be easily modified even in other communication systems and applied thereto.

Embodiments of the disclosure relate to an apparatus and method to enable the controlling of O-RU by an RIC in a radio access network. In particular, it provides at least one new interface and at least one new Information Element (IE) for intelligent control and configuration of O-RU, in accordance with an open radio access network (O-RAN) standard of a wireless communication system.

Further, embodiments provide an apparatus and method for transmitting a list of IDs of the RUs that are to be configured. Embodiments further provide a list of IEs, apparatus and method for configuring an O-RU node by the RIC according to the aforementioned O-RU ID list, so that the particular O-RU will work according to the control of the RIC.

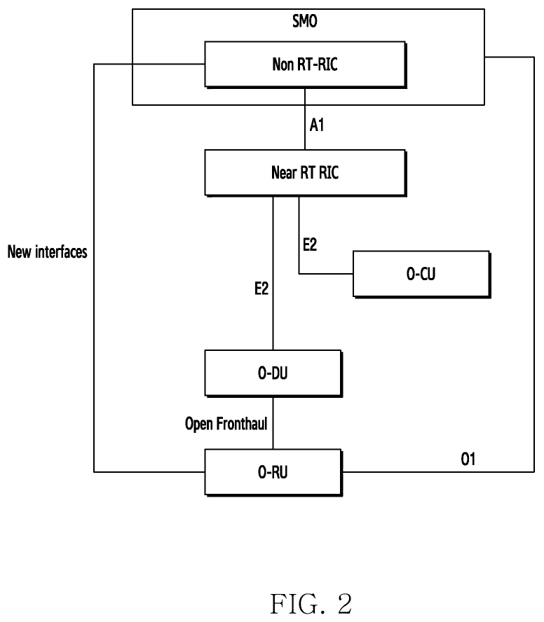

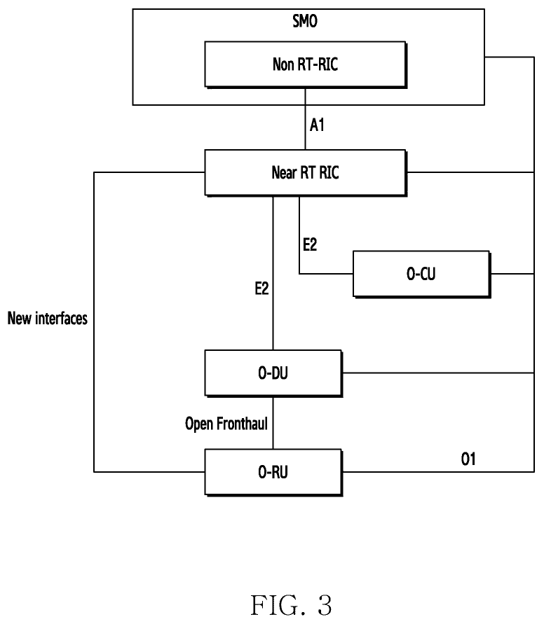

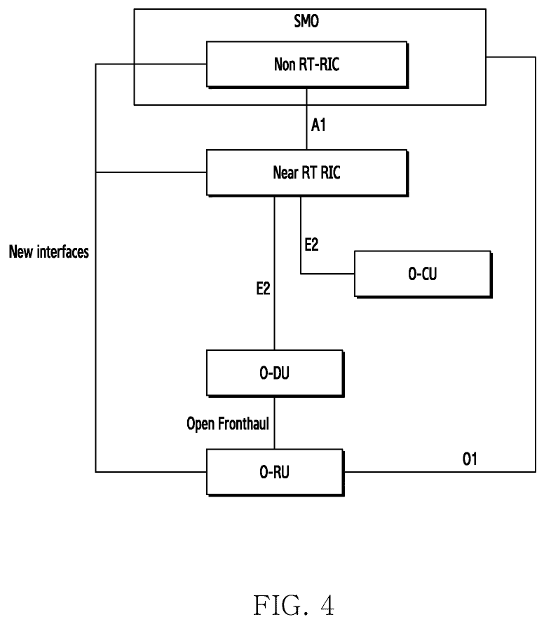

FIGS. 2-4 show certain examples of new interfaces (labelled as such) in the context of an O-RAN architecture. The known interfaces from the prior art are labelled with their usual names. Note that in FIGS. 3 and 4 the new interfaces are different from the prior art O1 interface shown, because O1 is the management interface while the new interface contains RU Control configurations. Also note the new interfaces between non- and near-RT RIC to O-RU may need exposure of parameters/data from internal functional blocks in non- and near-RT RIC, such as any AI/ML functions.

In the following, the new parameters, interfaces, and procedures are described for each method, respectively.

Embodiments of the disclosure provide at least one of the following features:
1. New enabler within non-RT RIC and near-RT RIC for O-RU configuration and control. This includes one or multiple new rApps/xApps, namely the O-RU control xApps, at non-RT RIC or near-RT RIC
2. New RU Service Model CONTROL service style, between non-RT RIC/near-RT RIC and the RU control function at the O-RU, where the new control model allows the configuration of RU according to the actions from the xApps in near-RT RIC, or rApps from non-RT RIC specified in point 1 above.
3. New interfaces between non-RT RIC/near-RT RIC and the O-RU, where the interfaces are: 1) a list of the IDs of the RU components to be configured; 2) parameters of the RUs to be configured, e.g., antenna tilt, ADC quantisation level, etc.
4. Acknowledge of completion of actions from O-RU to non-RT RIC or near-RT RIC (e.g., Ack or NAck of actions) through the newly defined interfaces.
5. O-RU reporting of parameters update after action.
6. A procedure related to enabling the control of O-RU with the new interfaces and IEs above.

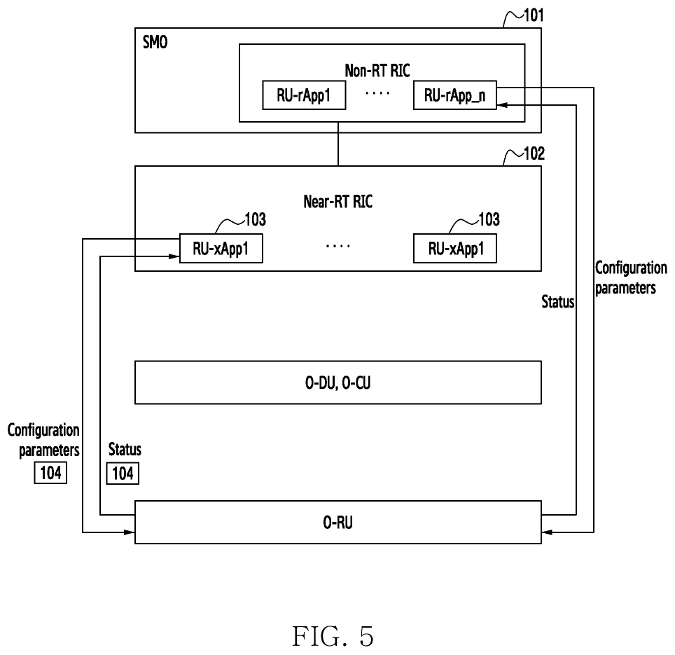

FIG. 5 shows a high level architecture of an embodiment of the present disclosure. As illustrated in FIG. 5, the non-RT RIC (101) in service orchestration and management (SMO) framework enables non-real-time control and optimization of RAN elements and resources and policy-based guidance to the applications/features in Near-RT RIC (102) through an A1 interface.

In one embodiment of the disclosure, one or multiple xApps are added, i.e., the O-RU control xApps (103) in Near-RT RIC. The xApp makes a decision on, e.g., quantisation levels of the ADCs, the antenna tilt, etc., according to the Key Performance Indicators (KPIs) of the network and/or policies from the SMO.

The decision made by 103 may lead to update of the list of RUs to be configured. These parameters (104) shall be passed from near-RT RIC to O-RU, and O-RU shall be configured accordingly and dynamically. The O-RU shall send their status monitoring (104) (e.g., current quantisation level, ADC characteristics, antenna tilt etc.) to near-RT RIC, for 103 to update its decisions accordingly.

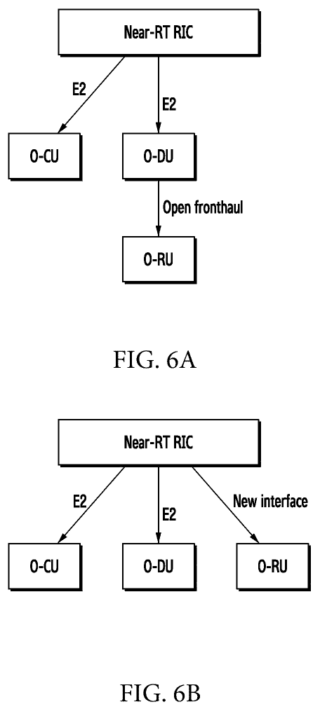

From an architecture point of view, with the new interface, the new interface enables the configuration of O-RU directly by near-RT RIC, rather than by using open fronthaul from E2 nodes. An illustration of such a concept is shown in FIG. 6B, which is contrasted with FIG. 6A, which shows the prior situation.

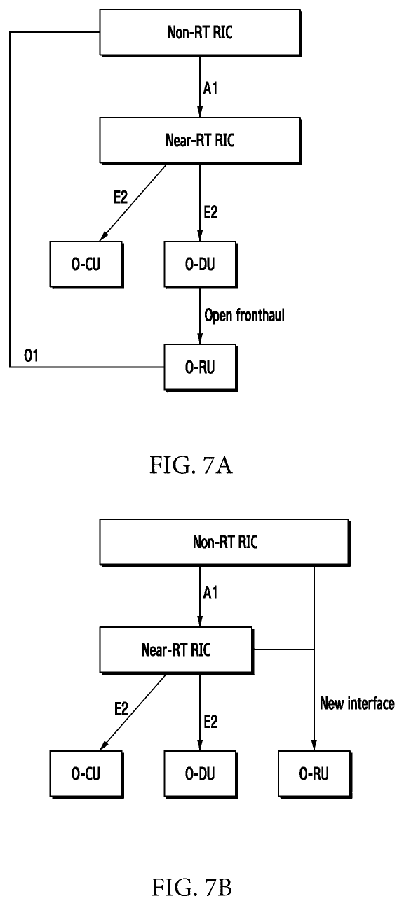

In another embodiment of the disclosure, with the new interface, the new interface enables the configuration of O-RU directly by non-RT RIC, rather than via the O1 interfaces. An illustration of such a concept is given in FIG. 7B, which is contrasted with FIG. 7A, which shows the prior situation.

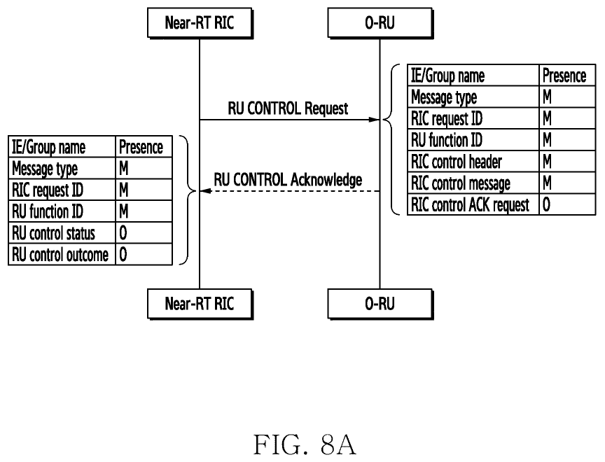

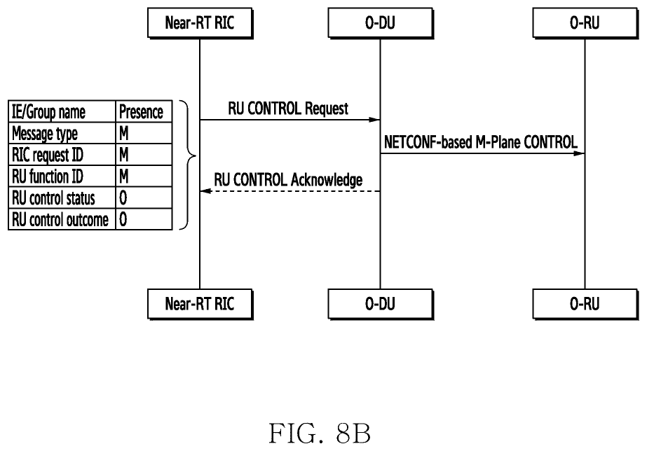

O-RAN Near-RT RIC can control O-RU nodes through RU Application Protocol message, RUAP RIC Control Request Message. The associated message flows and Message Information Elements (IE) are shown in FIG. 8A (showing direct control mode) and FIG. 8B (showing hierarchy mode).

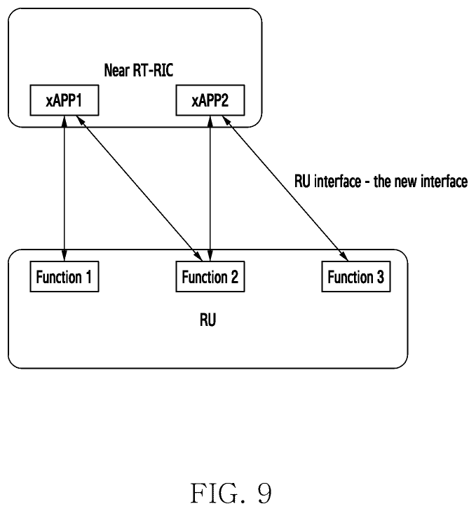

FIG. 9 shows the interactions between xApps and RU functions. In one example, the xApp may configure the parameters of Analog to Digital Controllers (ADCs), and the RU function may be an ADC. In another example, the xApp may control the non-linearity of a power amplifier (PA), and the RU function may be a PA.

Table 1 below shows a header format used in an embodiment. This Control header format is part of the RIC CONTROL message sent by the Near-RT RIC to an O-RU and is required for RIC Control Procedure.

TABLE 1
Control header format is part of the RIC CONTROL message

| | | | | |
|---|---|---|---|---|
| | | | IE type and | Semantics |
| IE/Group Name | Presence | Range | reference | description |

| | |
|---|---|
| CHOICE Control | |
| Header Format | |
| >E2SM-CCC Control | M |
| Header Format xx | |

Table 2 below shows a Control Header format.

TABLE 2
Control Header format

| | | | | |
|---|---|---|---|---|
| | | | IE type and | Semantics |
| IE/Group Name | Presence | Range | reference | description |

| | | |
|---|---|---|
| RIC Style Type | M | x.x.x |

Table 3 below shows a Control message format.

This information element is part of the RIC CONTROL message sent by the Near-RT RIC to an E2 Node, in this case, E2SM-CCC Control Message Format xx, it sent to O-RU and is required for RIC Control Procedure.

TABLE 3
E2SM-CCC Control Message Format xx

| | | | | |
|---|---|---|---|---|
| | | | IE type and | Semantics |
| IE/Group Name | Presence | Range | reference | description |

| | |
|---|---|
| CHOICE Control | |
| Message Format | |
| >E2SM-CCC Control | M |
| Message Format 1 | |
| >E2SM-CCC Control | M |
| Message Format 2 | |
| >E2SM-CCC Control | M |
| Message Format xx | |

Table 4 below shows E2SM-CCC Control Message Format xx showing the O-RU configuration information. It could have previous O-RU configuration information and new O-RU configuration information. Information is in an OCTET string container, and can be further defined later in the standard, as needed.

TABLE 1
E2SM-CCC Control Message Format xx

| IE/Group | | | IE type and | |
|---|---|---|---|---|
| Name | Presence | Range | reference | Semantics description |
| List of | | 1 . . . <maxnoofConfigurations> | | Indicates the configuration |
| Configuration | | | | structures that are controlled |
| Structures | | | | within the message. |
| >RU | M | | | Indicates the RAN |
| Configuration | | | | Configuration Structure name. |
| Structure | | | | |
| Name | | | | |
| >Old Values | O | | OCTET | Provides the old attribute values |
| of Attributes | | | STRING | for the respective O-RU |
| | | | | Configuration Structure. |
| >New Values | O | | OCTET | Provides the new attribute |
| of Attributes | | | STRING | values for the respective O-RU |
| | | | | Configuration Structure |

The following relates to an example use case for O-RU configuration via xApps/rApps.

Prior art O-RAN architecture supports the configuration of O-RU through the O1 interface. In the next generation network, there are a few use cases that will need O-RU configuration via xApps and rApps. For example, AI can be used to enhance Power Amplifier (PA) non-linearity, optimise ADC quantisation bits, and optimize antenna tilt and beam etc.

### 1. The PA Non-Linearity Use Case:

The PA Non-Linearity Use Case focuses on addressing the significant energy consumption of base stations in mobile telecommunications, where 60-80% of the energy footprint is attributed to base stations and 60-80% of that is due to Linear Power Amplifiers (LPAs) being constantly active and transmitting at much higher power levels than User Equipment (UEs) with relatively low efficiency. Recently, various algorithms have been introduced to enhance LPA efficiency.

AI techniques can predict and compensate for the non-linear behaviour of LPAs, allowing for more efficient power usage and reduced energy consumption. For instance, in Ma, Rui, et al. “A New Frontier for Power Amplifier enabled by Machine Learning.” MICROWAVE JOURNAL 64.4 (2021): 22-32, the authors demonstrate how compact data-driven AI techniques can unlock the full potential of high-performance power amplifiers for flexible and wideband wireless applications.

In J. Lu et al., “Machine Learning based Adaptive Predistorter for High Power Amplifier Linearization,” 2019 IEEE Cognitive Communications for Aerospace Applications Workshop (CCAAW), Cleveland, OH, USA, 2019, pp. 1-6, doi: 10.1109/CCAAW.2019.8904896, modern machine learning (ML) methods are proposed for predicting the dynamic non-linear behaviour of wideband RF power amplifiers (PAS).

In Towards 6G AI: AI-based Non-linearity Compensator, https://research.samsung.com/blog/Towards-6G-AI-AI-based-Non-linearity-Compensator, a technology that expands uplink communication coverage by allowing a UE to boost transmit power for a given PA is introduced, where increased non-linearity induced by the PA due to power-boosting is compensated at the base station receiver employing AI.

As a result of the above examples, a new interface between the O-RU and the Near-RT RIC is desirable not only for data collection and O-RU components monitoring but also for the control and improvement of individual components, such as PA efficiency. Additionally, such a new interface enables future disaggregation of O-RU components and offloads some signal processing tasks to xApps, reducing O-RU processing requirements in a near real-time manner.

According to the latest O-RAN alliance specifications, O-RAN-WG7.OMAC.HRD.0-R003-v02.00 “O-RAN Working Group 7 Whitebox Hardware Hardware Reference Design Specification for Outdoor Macrocell with Split Architecture Option 7.2”, Power Amplifier Interface specifications are limited to those shown on Table 5, below, and can be provided through the O1 and/or the open fronthaul for the Non-RT RIC and O-DU, respectively.

However, there is no direct interface to the Near-RT RIC, which is crucial for real-time processing flexibility in O-RAN. Furthermore, O-RAN specifications do not detail how mMIMO PAs configuration can be automated to optimize which PA will be enabled and disabled for power-efficient RF chain transmission.

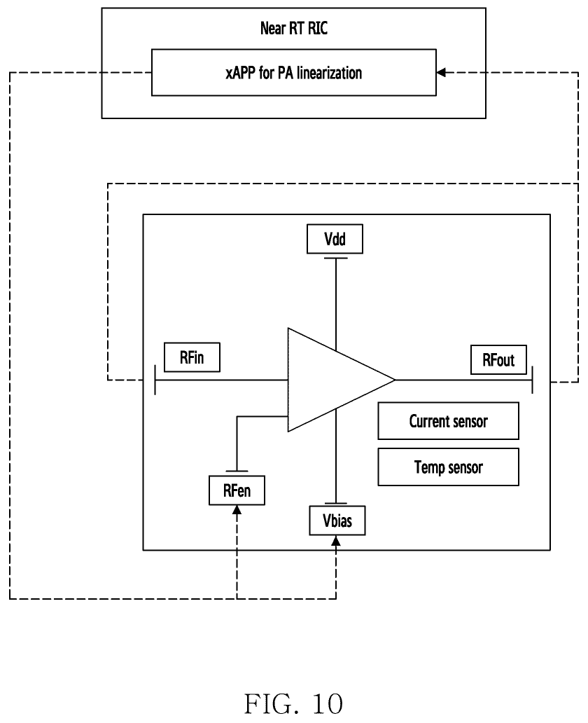

Embodiments of the disclosure provide that the new interface supports the PA Bias conditions (e.g., Drain bias current, High-voltage supply line, and on-chip temperature) as shown in Table 6 and FIG. 10, enabling O-RU data collection, monitoring, real-time enable/suspend, control, override messages (e.g., O-DU messages), and execution of xApp commands for O-RU PA components directly to and from the Near-RT RIC.

TABLE 5
Power Amplifier Interface Specifications

| Item | |
|---|---|
| Name | Description |
| RF | The enable input should be compatible with 1.8 V logic and |
| Enable | tolerate 3.3 V as required. A logic high enables the PA. |
| | A logic low disables the device and places it in a minimum |
| | dissipation mode. |
| RF | RF outputs support 50-ohm single ended to properly interface |
| Output | to a directional coupler, isolator, switch, or antenna. |
| RF | RF inputs should support 50-ohm, single ended match to the |
| Input | transceiver output or preamp. |

The new interface set out in an embodiment of this disclosure can be used to configure various parameters to optimize PA performance and energy efficiency. Some examples of these parameters include:

Bias conditions: The interface can control and configure bias conditions for the PA, such as drain bias current, high-voltage supply line, and on-chip temperature, allowing for optimal operation and energy efficiency, L. Riordan “Discrete and Integrated Control of Power Amplifiers in Base-Station Applications” https://www.analog.com/en/analog-dialogue/articles/power-amplifier-control-in-base-stations.html.

Operating mode: The interface can enable or disable different operating modes of the PA, such as linear mode for better signal quality or non-linear mode for higher power efficiency, depending on the requirements of the specific communication scenario.

Input and output power levels: The interface can be used to dynamically adjust the input and output power levels of the PA based on real-time network conditions, traffic load, and user equipment requirements.

Gain control: The interface can control the gain settings of the PA, enabling precise control of the output power and linearity, as well as reducing power consumption when the required output power is lower.

Load impedance tuning: The interface can be used to control and configure the load impedance of the PA to match the antenna impedance for optimal power transfer and reduced energy loss.

Temperature compensation: The interface can be used to monitor the PA's temperature and adjust the operating parameters accordingly to maintain optimal performance and prevent thermal degradation.

Pre-distortion settings: The interface can control and configure the PA's pre-distortion settings to compensate for non-linearities in the PA's response, improving signal quality and reducing distortion.

TABLE 6
Examples for possible monitorable and configurable parameters
via the new interface for PA non-linearity

| Parameter | | Parameter | |
|---|---|---|---|
| ID | Parameter | Value Type | Semantics Description |
| P1 | Bias | Numeric | Control and configure bias conditions |
| | conditions | (Volts, Amps) | for the PA, such as drain bias current, |
| | | | high-voltage supply line, and on-chip |
| | | | temperature. |
| P2 | Operating | Linear, Non- | Enable or disable different operating |
| | mode | linear | modes of the PA, such as linear mode |
| | | | for better signal quality or non-linear |
| | | | mode for higher power efficiency. |
| P3 | Input and | Numeric | Dynamically adjust the input and |
| | output power | (dBm) | output power levels of the PA based on |
| | levels | | real-time network conditions, traffic |
| | | | load, and user equipment requirements. |
| P4 | Gain control | Numeric (dB) | Control the gain settings of the PA, |
| | | | enabling precise control of the output |
| | | | power and linearity, as well as |
| | | | reducing power consumption. |
| P5 | Load | Numeric | Control and configure the load |
| | impedance | (Ohms) | impedance of the PA to match the |
| | tuning | | antenna impedance for optimal power |
| | | | transfer and reduced energy loss. |
| P6 | Temperature | Numeric (° C.) | Monitor the PA's temperature and |
| | compensation | | adjust the operating parameters |
| | | | accordingly to maintain optimal |
| | | | performance and prevent thermal |
| | | | degradation. |
| P7 | Pre-distortion | Numeric, | Control and configure the PA's pre- |
| | settings | Enable/Disable | distortion settings to compensate for |
| | | | non-linearities in the PA's response, |
| | | | improving signal quality and reducing |
| | | | distortion. |

### 2. ADC Quantization Bits Optimization:

The ADC quantization bits optimization use case focuses on improving the efficiency and performance of the ADC in a radio access network by intelligently adapting the number of quantization bits, as well as other ADC settings.

ADCs are responsible for converting analog signals from the radio frequency (RF) domain into digital signals that can be processed by digital signal processors (DSPs). The quantization process involves discretizing the continuous analog signal into a finite number of levels, which are represented by a specific number of bits. The number of quantization bits determines the resolution and accuracy of the digitized signal and directly impacts the signal quality and the overall system performance.

The ADC quantization optimization may be performed for one or more of the following scenarios/settings:
Dynamic Adjustment of Quantization Bits: In this use case, the RIC employs AI-driven algorithms to dynamically adjust the number of quantization bits used by the ADC based on the network conditions and requirements. For example, when the network is experiencing high traffic or when high signal fidelity is necessary, the RIC might increase the number of quantization bits to ensure better signal quality. On the other hand, during periods of low traffic or when signal quality requirements are less stringent, the RIC could reduce the number of quantization bits to save power and reduce overall system complexity.
Sampling Rate Optimization: Along with the number of quantization bits, the sampling rate of the ADC is another crucial factor affecting the signal quality and system performance. The RIC can adapt the ADC sampling rate based on the bandwidth requirements of the network, optimizing the trade-off between signal quality and energy consumption. For instance, during periods of low traffic, a lower sampling rate can be used to save energy without significantly impacting the signal quality.
Dynamic Range Adaptation: The dynamic range of the ADC is the range of input signal amplitudes it can accurately convert. In this use case, the RIC can optimize the dynamic range of the ADC based on the signal conditions and network requirements. For example, in situations with high interference or noise, the RIC might increase the dynamic range to ensure that the useful signal components are accurately captured and converted.
Noise Reduction and Filtering: The RIC can apply noise reduction and filtering techniques to improve the signal quality and reduce the impact of noise and interference on the digitized signal. This may involve adjusting the ADC's internal filtering settings or applying external digital signal processing techniques to the converted signal.

Overall, embodiments of the disclosure provide a new interface where xApps and rApps may modify the ADC configuration parameters which include:
Quantization Bits: The RIC can remotely adjust the number of quantization bits used by the ADC. By increasing or decreasing the number of bits, the RIC can balance the trade-off between signal quality, resolution, and system complexity.
Sampling Rate: The RIC can control the sampling rate of the ADC, which determines the rate at which the continuous analog signal is sampled and converted into discrete digital values. Optimizing the sampling rate based on bandwidth requirements and network conditions can enhance the efficiency of the conversion process.
Dynamic Range: The RIC can configure the dynamic range of the ADC, which is the range of input signal amplitudes the ADC can accurately convert. By optimizing the dynamic range, the RIC can ensure that the useful signal components are captured and converted effectively, even in challenging signal conditions.
Input Voltage Range: The RIC can set the input voltage range for the ADC, which affects the ADC's sensitivity and noise performance. By adjusting the input voltage range, the RIC can optimize the ADC's performance for the specific network conditions and signal characteristics.
Filtering Settings: The RIC can configure the ADC's internal filtering settings or apply external digital signal processing techniques to the converted signal. This can help reduce noise and improve signal quality in the digital domain.
Operating Modes: The RIC can control the operating modes of the ADC, such as power-saving or high-performance modes, to balance power consumption and performance based on network requirements.
Performance Monitoring and Feedback: The RIC can set parameters related to the collection and reporting of ADC performance metrics. This can include specifying the metrics to be monitored (e.g., signal-to-noise ratio, error rates, power consumption), the reporting intervals, and any thresholds or triggers for adaptive control.

Table 7 below gives a summary of the possible configurations via the new interface for ADC.

TABLE 7
Proposed DAC/ADC Interface Specifications for O-RU

| Parameter | | Parameter | |
|---|---|---|---|
| ID | Parameter | Value Type | Semantics Description |
| P1 | Quantization | Numeric | Remotely adjust the number of |
| | Bits | (bits) | quantization bits used by the ADC to |
| | | | balance the trade-off between signal |
| | | | quality, resolution, and system |
| | | | complexity. |
| P2 | Sampling | Numeric | Control the sampling rate of the ADC, |
| | Rate | (Samples/ | optimizing the rate based on bandwidth |
| | | second) | requirements and network conditions. |
| P3 | Dynamic | Numeric | Configure the dynamic range of the |
| | Range | (dB) | ADC, ensuring the useful signal |
| | | | components are captured and converted |
| | | | effectively. |
| P4 | Input | Numeric | Set the input voltage range for the ADC, |
| | Voltage | (Volts) | affecting the ADC's sensitivity and noise |
| | Range | | performance. |
| P5 | Filtering | Enable/ | Configure the ADC's internal filtering |
| | Settings | Disable, | settings or apply external digital signal |
| | | Numeric | processing techniques to the converted |
| | | | signal. |
| P6 | Operating | Power- | Control the operating modes of the ADC |
| | Modes | saving, High- | to balance power consumption and |
| | | performance | performance based on network |
| | | | requirements. |
| P1 | Quantization | Numeric | Remotely adjust the number of |
| | Bits | (bits) | quantization bits used by the ADC to |
| | | | balance the trade-off between signal |
| | | | quality, resolution, and system |
| | | | complexity. |

### 3. Antenna Tilt and Beam Optimization:

The Antenna Tilt and Beam Optimization use case focuses on improving the performance and efficiency of radio access networks, particularly in massive MIMO (systems, by intelligently managing and optimizing antenna settings such as tilt angles, beamforming weights, and beam steering directions. The main goal is to enhance network capacity, coverage, and overall performance while minimizing interference and power consumption.

In the following an expanded view of the Antenna Tilt and Beam Optimization use case is provided:
Adaptive Antenna Tilt Adjustment: The RIC employs AI-driven algorithms to dynamically adjust the antenna tilt angles based on real-time network conditions, user distribution, and performance requirements. By optimizing the antenna tilt, the RIC can focus the antenna's radiation pattern towards areas with higher user density or areas that require improved coverage, maximizing the network's efficiency and minimizing interference with other cells.
Intelligent Beamforming: Beamforming is a technique used in massive MIMO systems to transmit and receive signals in specific directions, enhancing the signal strength at the receiver and improving overall network capacity. The RIC can adaptively adjust the beamforming weights for each antenna element based on the user's locations and the network conditions, ensuring that the desired signal is transmitted or received in the most efficient manner possible. In mmWave transmission, beamforming is particularly advantageous for improving signal-to-noise ratios (SNR) and reducing interference between User Equipment (UE) signals in high-density environments. The O-RU mMIMO architecture features a beamformer block and supports precoding in the O-RU (Category B). However, the open front-haul interface used for beam configuration struggles to meet ultra-low latency requirements. Beam Mobility Management (BMM) is an O-RAN use case that employs the Grid of Beams (GoB) beamforming method, with various xApps proposed to minimize beam failure and maximize SNR. The E2 interface can present a time bottleneck for transmitting necessary data from the O-RU and configuration messages from xApps. Consequently, a new interface between the O-RU and Near-RT RIC is needed to reduce latency for both data collection and control signals. For example, some Downlink (DL) precoding parameters sent by O-RAN using the open Front-Haul (FH) interface between the O-DU and O-RU are listed in Table 8 e.g. O-RAN.WG4.CUS.0-v10.00 “O-RAN Working Group 4 (Open Fronthaul Interfaces WG) Control, User and Synchronization Plane Specification”.
Dynamic Beam Steering: Beam steering involves directing the antenna's main radiation lobe towards the desired user or group of users to improve signal quality, minimize interference, and increase network capacity. The RIC can dynamically steer the antenna beams based on user distribution, mobility patterns, and network conditions, ensuring that the network can adapt to changing user requirements and maintain optimal performance.
Interference Management: By intelligently adjusting the antenna tilt, beamforming weights, and beam steering directions, the RIC can minimize interference between neighboring cells and reduce the impact of external sources of interference. This can lead to improved signal quality, reduced call drops, and better overall network performance.
Energy Efficiency: Antenna Tilt and Beam Optimization can also contribute to energy efficiency in radio access networks. By focusing the transmitted energy in the desired directions and avoiding wasteful energy dispersion, the network can achieve its performance objectives with lower power consumption. This can be particularly beneficial in dense urban environments or during periods of low network traffic.
Performance Monitoring and Feedback: The RIC continuously monitors key performance metrics, such as signal-to-interference-plus-noise ratio (SINR), cell load, and user satisfaction, and uses this information to adapt the antenna settings in real-time. This allows the RIC to maintain optimal network performance and respond to changing conditions quickly and effectively.

TABLE 8
O-RU DL Precoding configuration parameters example.

| Parameter Name | Description |
|---|---|
| codebookIndex | precoder codebook used for transmission |
| LayerID | Layer ID for DL transmission |
| crsReMask | CRS resource element mask |
| txScheme | transmission scheme |
| beamIdAP1 | beam id to be used for antenna port 1 |
| beamIdAP2 | beam id to be used for antenna port 2 |

In summary, the Antenna Tilt and Beam Optimization use case focuses on intelligently managing and optimizing antenna settings in a RAN to enhance network capacity, coverage, and overall performance while minimizing interference and power consumption. The interface enables the RIC to configure and control various parameters to improve network performance, including but not limited to:
Antenna Tilt Angle: The RIC can remotely adjust the electrical and/or mechanical tilt angles of antenna elements to optimize coverage and minimize interference. Both downtilt and uptilt angles can be modified based on network conditions and user distribution.
Beamforming Weights: The RIC can control complex weights applied to each antenna element in the array, forming the desired radiation pattern. Optimizing these weights helps maximize signal strength at the receiver, enhance network capacity, and reduce interference.
Beam Steering Direction: The RIC can configure the main radiation lobe's direction to improve signal quality, minimize interference, and increase network capacity. This may involve specifying azimuth and elevation angles or providing desired spatial coordinates for the main lobe.
Transmit Power: The RIC can control the transmit power of individual antenna elements or the overall array, adjusting power levels based on network conditions, user requirements, and energy-saving objectives.
Antenna Polarization: The RIC can configure antenna element polarization (e.g., vertical, horizontal, or circular) to enhance signal quality and mitigate multipath fading.
Antenna Array Geometry: In some instances, the RIC may adjust the physical layout or arrangement of antenna elements within the array to optimize the radiation pattern and maximize network performance.
VM Resolution: The RIC can control the number of bits resolution for vector modulators (VM) to manage phase.
DVGA Resolution: The RIC can control digital variable gain amplifiers (DVGAs) to manage amplitude.
Beamformer On-Chip LDO: The RIC can configure the voltage regulator that generates voltage supply for the serial port interface circuitry, reducing the number of supply domains required and enabling fast startup and control during normal operation.
RF Power Overload Circuit: The RIC can manage a receive channel overload detection circuit to prevent potential device damage due to blocker instances.

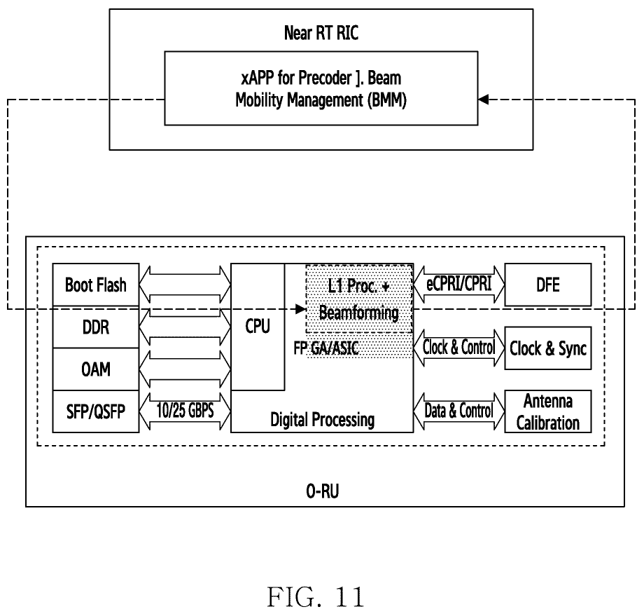

The new interface supports the AI/ML flow works and can provide a new service for beamforming monitoring and controlling, including, for example, the ones are listed in Table 9 along with FIG. 11.

TABLE 9
DL Antenna Tilt and Beam (include the precoder in the O-RU)
Optimization monitoring and configuration parameters example

| Parameter | | Parameter | |
|---|---|---|---|
| ID | Parameter | Value Type | Semantics Description |
| P1 | Antenna Tilt | −20 to 10 | Remotely adjust the electrical and/or |
| | Angle | degrees | mechanical tilt angles of antenna |
| | | | elements to optimize coverage and |
| | | | minimize interference. |
| P2 | Beamforming | Complex | Control complex weights applied to |
| | Weights | numbers | each antenna element in the array, |
| | | | forming the desired radiation pattern. |
| P3 | Beam | Azimuth, | Configure the main radiation lobe's |
| | Steering | Elevation | direction to improve signal quality, |
| | Direction | angles or | minimize interference, and increase |
| | | spatial | network capacity. |
| | | coordinates | |
| P4 | Transmit | Numeric | Control the transmit power of |
| | Power | (dBm) | individual antenna elements or the |
| | | | overall array, adjusting power levels |
| | | | based on network conditions. |
| P5 | Antenna | Vertical, | Configure antenna element |
| | Polarization | Horizontal, | polarization to enhance signal quality |
| | | Circular | and mitigate multipath fading. |
| P6 | Antenna | Layout or | Adjust the physical layout or |
| | Array | arrangement | arrangement of antenna elements |
| | Geometry | | within the array to optimize the |
| | | | radiation pattern and maximize |
| | | | network performance. |
| P7 | VM | Numeric (bits) | Control the number of bits resolution |
| | Resolution | | for vector modulators (VM) to manage |
| | | | phase. |
| P8 | DVGA | Numeric (bits) | Control digital variable gain amplifiers |
| | Resolution | | (DVGAs) to manage amplitude. |
| P9 | Beamformer | Numeric | Configure the voltage regulator that |
| | On-Chip | (Volts) | generates voltage supply for the serial |
| | LDO | | port interface circuitry. |
| P10 | RF Power | Enable/Disable | Manage a receive channel overload |
| | Overload | | detection circuit to prevent potential |
| | Circuit | | device damage due to blocker |
| | | | instances. |

### 4. PA Activation and Deactivation:

The PA Activation and Deactivation use case focuses on intelligently managing the activation and deactivation of power amplifiers in a radio access network, specifically in massive MIMO (Multiple-Input, Multiple-Output) systems. This use case aims to optimize the RF chain transmission's power efficiency while maintaining network performance, which is particularly important in energy-saving scenarios.

In massive MIMO systems, numerous power amplifiers are utilized to drive the antenna elements. By selectively activating or deactivating specific PAs, the network can reduce energy consumption without compromising the required level of network performance. The following lists certain possible optimization scenarios that involve PA activation/deactivation:
Dynamic PA Activation and Deactivation: The RIC employs AI-driven algorithms to dynamically activate or deactivate PAs based on real-time network conditions, traffic load, and specific performance requirements. For example, during periods of low network traffic, some PAs can be deactivated to save energy while still maintaining the required level of network performance. Conversely, when network traffic is high, the RIC may activate more PAs to handle the increased demand and ensure reliable communication.
Energy-Efficient PA Selection: The RIC can adaptively select which PAS to activate or deactivate, considering factors such as energy efficiency, PA performance, and network conditions. This adaptive selection may involve analyzing the individual PA energy consumption, output power, and efficiency, enabling the RIC to choose the most energy-efficient PAs for activation.
PA Load Balancing: To ensure optimal performance and prevent excessive wear on specific PAs, the RIC can balance the workload across the available PAs. Load balancing strategies can involve periodically alternating the active PAs or assigning PAs to different antenna elements or sectors based on their energy efficiency and performance characteristics.
Proactive Maintenance and Monitoring: The RIC continuously monitors the performance metrics of the PAs, such as temperature, output power, and efficiency, and uses this information to inform its activation and deactivation decisions. By analyzing the performance data, the RIC can identify potential issues or inefficiencies and take appropriate corrective actions, such as adjusting the PA settings or scheduling maintenance.
Integration with Energy-Saving Scenarios: PA Activation and Deactivation plays a crucial role in energy-saving scenarios, such as sleep mode or low-power mode. In these scenarios, the RIC can deactivate a significant portion of the PAs, reducing the overall energy consumption of the network. Furthermore, the RIC can intelligently reactivate PAs when network traffic increases or when specific performance requirements demand it.

Based on the aforementioned scenarios, the set of parameters that can be configured through the new interface are:
PA Activation Status: The RIC can remotely activate or deactivate individual PAs or groups of PAs based on real-time network conditions, traffic load, and specific performance requirements.
PA Output Power: The RIC can control the output power of each PA, adjusting the power levels to balance network performance, coverage, and energy efficiency.
PA Operating Modes: The RIC can configure different operating modes for the PAs, such as power-saving or high-performance modes, to balance power consumption and performance based on network requirements.
PA Bias Settings: The RIC can adjust the bias settings of the PAs, which can have a significant impact on their efficiency, linearity, and power consumption. By optimizing the bias settings, the RIC can improve the overall energy efficiency of the radio access network.
Load Balancing: The RIC can control the allocation of RF transmission tasks among the available PAs, ensuring an even distribution of workload and preventing excessive wear on specific PAs.

Table 10 summarize the examples of parameters that can be configured through the new interface.

TABLE 10
Examples for possible configurations via the new interface
for Antenna PA Activation and Deactivation

| Parameter | | Parameter | |
|---|---|---|---|
| ID | Parameter | Value Type | Semantics Description |
| P1 | Antenna Tilt | −20 to 10 | Remotely adjust the electrical and/or |
| | Angle | degrees | mechanical tilt angles of antenna |
| | | | elements to optimize coverage and |
| | | | minimize interference. |
| P2 | Beamforming | Complex | Control complex weights applied to |
| | Weights | numbers | each antenna element in the array, |
| | | | forming the desired radiation pattern. |
| P3 | Beam | Azimuth, | Configure the main radiation lobe's |
| | Steering | Elevation | direction to improve signal quality, |
| | Direction | angles or spatial | minimize interference, and increase |
| | | coordinates | network capacity. |
| P4 | Transmit | Numeric (dBm) | Control the transmit power of |
| | Power | | individual antenna elements or the |
| | | | overall array, adjusting power levels |
| | | | based on network conditions. |
| P5 | Antenna | Vertical, | Configure antenna element |
| | Polarization | Horizontal, | polarization to enhance signal quality |
| | | Circular | and mitigate multipath fading. |

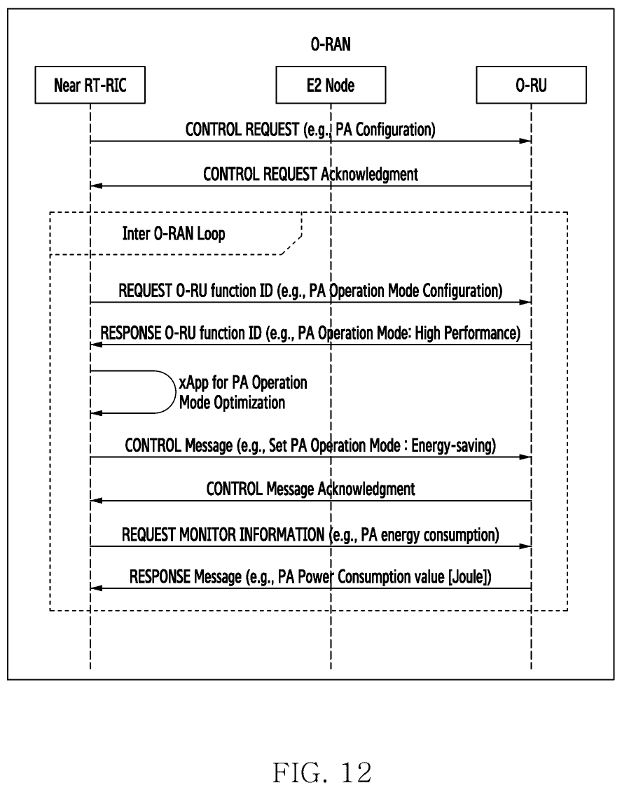

FIG. 12 shows an example procedure of PA configuration use case, it shows that the new interface allows inter loop between the Near RT-RIC and the O-RU to directly interact between each other.

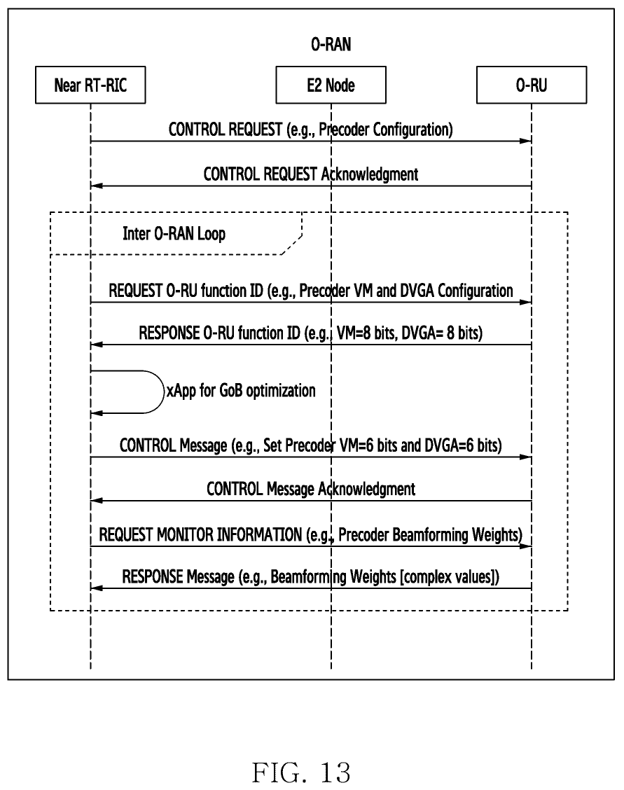

Further, FIG. 13 shows a second example procedure of an O-RU Precoder configuration use case.

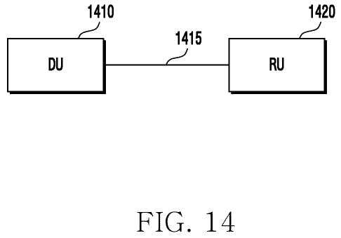

FIG. 14 illustrates a fronthaul interface according to an embodiment of the disclosure. A fronthaul refers to entities between a radio access network and a base station, as opposed to a backhaul between a base station and a core network. Although FIG. 14 illustrate an example of a fronthaul structure between the DU 1410 and one RU 1420, it is only for convenience of description and the disclosure is not limited thereto. In other words, an embodiment of the disclosure may also be applied to a fronthaul structure between one DU and a plurality of RUs. For example, an embodiment of the disclosure may be applied to a fronthaul structure between one DU and two RUs. Further, an embodiment of the disclosure may be also applied to a fronthaul structure between one DU and three RUs.

Referring to FIG. 14, the base station described above may include a DU 1410 and an RU 1420. The fronthaul 1415 between the DU 1410 and the RU 1420 may be operated through an Fx interface. For the operation of the fronthaul 1415, an interface, such as e.g., an enhanced common public radio interface (eCPRI) or a radio over ethernet (ROE) may be used.

Along with development of communication technology, the mobile data traffic has increased a great deal, and thus, the bandwidth requirement demanded by the fronthaul between the digital unit (DU) and the radio unit (RU) has increased significantly. In a deployment, such as a centralized/cloud radio access network (C-RAN), the DU may be implemented to perform the functions for packet data convergence protocol (PDCP), radio link control (RLC), media access control (MAC), and physical (PHY), and the RU may be implemented to further perform the functions for a PHY layer in addition to the radio frequency (RF) function.

The DU 1410 may serve as an upper layer of a wireless network. For example, the DU 1410 may perform a function of a MAC layer and a part of the PHY layer. Here, the part of the PHY layer is performed at a higher level amongst the functions of the PHY layer, and may include, for example, channel encoding (or channel decoding), scrambling (or descrambling), modulation (or demodulation), or layer mapping (or layer de-mapping). According to an embodiment of the disclosure, when the DU 1410 conforms to the O-RAN standard, it may be referred to as an O-DU (O-RAN DU). The DU 1410 may be represented replaced by a first network entity for a base station (e.g., gNB) in embodiments of the disclosure, as occasion demands.

The RU 1420 may be responsible for lower layer functions of the wireless network. For example, the RU 1420 may perform a part of the PHY layer and the RF function. Here, the part of the PHY layer is performed at a relatively lower level than the DU 1410 amongst functions of the PHY layer, and may include, for example, iFFT transform (or FFT transform), CP insertion (CP removal), and digital beamforming. The RU 1420 may be referred to as ‘access unit (AU)’, ‘access point (AP)’, ‘transmission/reception point (TRP)’, ‘remote radio head (RRH)’, ‘radio unit (RU)’, or any other terms having an equivalent technical meaning thereto. According to an embodiment of the disclosure, when the RU 1420 conforms to the O-RAN standard, it may be referred to as an O-RU (O-RAN RU). The RU 1420 may be represented replaced by a second network entity for a base station (e.g., gNB) in embodiments of the disclosure, as circumstance demands.

Although FIG. 14 describes that the base station described above, includes the DU 1410 and the RU 1420, the embodiments of the disclosure are not limited thereto. The base station according to embodiments of the disclosure may be implemented with a distributed deployment according to a centralized unit (CU) configured to perform a function of upper layers (e.g., packet data convergence protocol (PDCP), radio resource control (RRC)) of an access network, and a distributed unit (DU) configured to perform a function of a lower layer. In this occasion, the distributed unit (DU) may include a digital unit (DU) and a radio unit (RU) of FIG. 14. Between the core (e.g., 5G core (5GC) or next generation core (NGC)) network and the radio network (RAN), the deployment of the base station may be implemented in the order of CU, DU, and RU. The interface between the CU and the distributed unit (DU) may be referred to as an F1 interface.

The centralized unit (CU) may be connected to one or more DUs to act as a higher layer than the DU. For example, the CU may be responsible for the functions of radio resource control (RRC) and packet data convergence protocol (PDCP) layers, and the DU and the RU may be responsible for the functions of lower layers. The DU may perform some functions (high PHY) of the radio link control (RLC), the media access control (MAC), and the physical (PHY) layers, and the RU may be responsible for the remaining functions (low PHY) of the PHY layer. Further, as an example, the digital unit (DU) may be included in the distributed unit (DU) according to implementation of a distributed arrangement of the base station. Hereinafter, unless otherwise defined, the operations of the digital unit (DU) and the RU will be described, but it is to be noted that various embodiments of the disclosure may be applied to both a base station deployment including the CU or a deployment in which the DU is directly connected to a core network, that is, being incorporated into a base station (e.g., an NG-RAN node) where the CU and the DU are one entity.

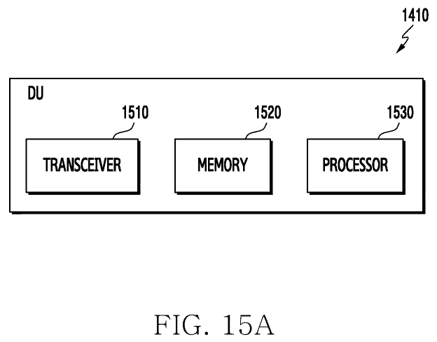

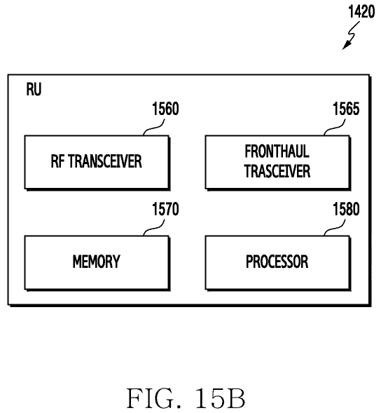

FIG. 15A illustrates a functional configuration of a distributed unit (DU) according to an embodiment of the disclosure.

The configuration illustrated in FIG. 15A may be understood as a configuration of the DU 1410 of FIG. 14 as a part of the base station. As used herein, the terms ‘˜ module’, ‘˜ unit’, or ‘˜ part’ mean a unit for processing at least one function or operation, which may be implemented by hardware, software, or a combination of hardware and software.

Referring to FIG. 15A, the DU 1410 includes a transceiver 1510, a memory 1520, and a processor 1530.

The transceiver 1510 may perform functions for transmitting and/or receiving signals in a wired communication environment. The transceiver 1510 may include a wired interface for controlling a direct connection between a device and another device through a transmission medium (e.g., copper wire, optical fiber, etc.). For example, the transceiver 1510 may transmit an electrical signal to other device through a copper wire or perform a conversion between an electrical signal and an optical signal. The DU 1410 may communicate with a radio unit (RU) via the transceiver 1510. The DU 1410 may be connected to a core network or a distributed CU via transceiver 1510.

The transceiver 1510 may perform the functions for transmitting and receiving signals in a wireless communication environment. For example, the transceiver 1510 may perform a function for conversion between a baseband signal and a bit string according to a physical layer standard of a system. For example, upon data transmission, the transceiver 1510 generates complex symbols by encoding and modulating a transmit bit string. Further, upon data reception, the transceiver 1510 restores the received bit string through demodulation and decoding of the baseband signal. Further, the transceiver 1510 may include a plurality of transmission/reception paths. Furthermore, according to an embodiment of the disclosure, the transceiver 1510 may be connected to a core network or connected to other nodes (e.g., integrated access backhaul (IAB).

The transceiver 1510 is configured to transmit and receive signals. For example, the transceiver 1510 may transmit a management plane (M-plane) message. For example, the transceiver 1510 may transmit a synchronization plane (S-plane) message. For example, the transceiver 1510 may transmit a control plane (C-plane) message. For example, the transceiver 1510 may transmit a user plane (U-plane) message. For example, the transceiver 1510 may receive the user plane message. Although only the transceiver 1510 is illustrated in FIG. 15A, the DU 1410 may include two or more transceivers, according to another embodiment.

The transceiver 1510 transmits and receives signals as described above. Accordingly, all or at least part of the transceiver 1510 may be also referred to as a communication unit, a transmission unit, a reception unit, or a transmission/reception unit. Further, throughout the description, it is to be noted that transmission and reception performed via a wireless channel are intended to include the aforementioned processing performed by the transceiver 1510.

Although not shown in FIG. 15A, the transceiver 1510 may further include a backhaul transceiver for connection with a core network or another base station. The backhaul transceiver provides an interface for performing communication with other nodes in the network. In other words, the backhaul transceiver converts a bit string transmitted from a base station to another node, for example, another access node, another base station, a higher node, a core network or the like, into a physical signal and converts the physical signal received from the other node into a bit string.

The memory 1520 stores data, such as a basic program, an application program, and setting information for an overall operation of the DU 1410. The memory 1520 may be referred to as a storage unit. The memory 1520 may be configured of a volatile memory, a nonvolatile memory, or a combination of a volatile memory and a nonvolatile memory. Further, the memory 1520 provides stored data according to a request of the processor 1530.

The processor 1530 controls the overall operations of the DU 1410. The processor 1530 may be referred to as a controller. For example, the processor 1530 transmits and receives signals through the transceiver 1510 (or via a backhaul communication unit). Further, the processor 1530 records and reads data into/from the memory 1520. Further, the processor 1530 may perform functions of a protocol stack required by the communication standard. Although only the processor 1530 is illustrated in FIG. 15A, the DU 1410 may include two or more processors, according to an example of another implementation.

The configuration of the DU 1410 illustrated in FIG. 15A is only of an example, and a configuration of the DU performing the embodiments of the disclosure is not limited to the configuration illustrated in FIG. 15A. In some embodiments of the disclosure, some of the configuration may be added, deleted, or changed.

FIG. 15B illustrates a functional configuration of a radio unit (RU) according to an embodiment of the disclosure.

The configuration illustrated in FIG. 15B may be understood as a configuration of the RU 1420 of FIG. 14, as a part of the base station. As used herein, the terms, such as ‘˜ module’, ‘˜ unit’, or ‘˜ part’ mean a unit for processing at least one function or operation, which may be implemented by hardware, software, or a combination of hardware and software.

Referring to FIG. 15B, the RU 1420 includes an RF transceiver 1560, a fronthaul transceiver 1565, a memory 1570, and a processor 1580.

The RF transceiver 1560 performs the functions for transmitting and receiving signals through a wireless channel. For example, the RF transceiver 1560 up-converts a baseband signal into an RF band signal to transmit the RF band signal through an antenna, and down-converts the RF band signal received through the antenna into the baseband signal. For example, the RF transceiver 1560 may include a transmission filter, a reception filter, an amplifier, a mixer, an oscillator, a DAC, an ADC, or the like.

The RF transceiver 1560 may include a plurality of transmission/reception paths. Furthermore, the RF transceiver 1560 may include an antenna unit. The RF transceiver 1560 may include at least one antenna array configured with a plurality of antenna elements. In terms of hardware, the RF transceiver 1560 may be configured with a digital circuit and an analog circuit (e.g., radio frequency integrated circuit (RFIC)). Here, the digital circuit and the analog circuit may be implemented in a single package. Further, the RF transceiver 1560 may include a plurality of RF chains. The RF transceiver 1560 may perform beamforming. The RF transceiver 1560 may apply a beamforming weight to a signal to be transmitted/received for assigning directionality according to the setting of the processor 1580. According to an embodiment of the disclosure, the RF transceiver 1560 may include a radio frequency (RF) block (or an RF part).

According to an embodiment of the disclosure, the RF transceiver 1560 may transmit and receive the signal over a radio access network. For example, the RF transceiver 1560 may transmit a downlink signal. The downlink signal may include a synchronization signal (SS), a reference signal (RS) (e.g., cell-specific reference signal (CRS), DM (demodulation)-RS)), system information (e.g., master information block (MIB), system information block (SIB), remaining system information (RMSI), other system information (OSI), configuration messages, control information, or downlink data. Further, for example, the RF transceiver 1560 may receive an uplink signal. The uplink signal may include a random access related signal (e.g., random access preamble (RAP) (or Msg1 (message 1), Msg3 (message 3)), a reference signal (e.g., sounding reference signal (SRS), DM-RS), a power headroom report (PHR) or the like. Although only the RF transceiver 1560 is illustrated in FIG. 15B, the RU 1420 may include two or more RF transceivers, according to another implementation example.

The fronthaul transceiver 1565 may transmit and receive a signal. According to an embodiment of the disclosure, the fronthaul transceiver 1565 may transmit and receive the signal on a fronthaul interface. For example, the fronthaul transceiver 1565 may receive a management plane (M-plane) message. For example, the fronthaul transceiver 1565 may receive a synchronization plane (S-plane) message. For example, the fronthaul transceiver 1565 may receive a control plane (C-plane) message. For example, the fronthaul transceiver 1565 may transmit a user plane (U-plane) message. For example, the fronthaul transceiver 1565 may receive the user plane message. Although only the fronthaul transceiver 1565 is illustrated in FIG. 15B, the RU 1420 may include two or more fronthaul transceivers, according to another implementation example.

The RF transceiver 1560 and the fronthaul transceiver 1565 transmit and receive signals as described above. As such, all or at least part of the RF transceiver 1560 and the fronthaul transceiver 1565 may be referred to as a communication unit, a transmission unit, a reception unit, or a transmission/reception unit. Further, throughout the following disclosure, transmission and reception performed through a radio channel are used to mean that the aforementioned processing is performed by the RF transceiver 1560.

The memory 1570 stores data, such as a basic program, an application program, and setting information for an overall operation of the RU 1420. The memory 1570 may be referred to as a storage unit. The memory 1570 may be configured with a volatile memory, a nonvolatile memory, or a combination of a volatile memory and a nonvolatile memory. Further, the memory 1570 provides stored data according to a request of the processor 1580. According to an embodiment of the disclosure, the memory 1570 may include a memory for storing conditions, instructions, or set values related to embodiments of the disclosure.

The processor 1580 controls the overall operations of the RU 1420. The processor 1580 may be referred to as a controller. For example, the processor 1580 transmits and receives signals through the RF transceiver 1560 or the fronthaul transceiver 1565. Further, the processor 1580 writes and reads data into/from the memory 1570. Then, the processor 1580 may perform the functions of the protocol stack required by the communication standard. Although only the processor 1580 is illustrated in FIG. 15B, the RU 1420 may include two or more processors, according to another implementation example. The processor 1580 may include a storage space for storing instructions/codes that are at least temporarily residing in the processor 1580, as the instructions/codes being an instruction set or code stored in the memory 1570. The processor 1580 may further include various communication modules for performing communication. The processor 1580 may control the RU 1420 to perform operations according to the following embodiments of the disclosure.

The configuration of the RU 1420 illustrated in FIG. 15B is only of an example, and the example of the RU performing the embodiments of the disclosure is not limited to the configuration illustrated in FIG. 15B. In some configurations, some of the configuration may be added, deleted, or changed.

Although components of the DU-RU are shown and described as being separated, implementation examples are not limited thereto. As an implementation example of the present disclosure, of course, one device including a DU and an RU may perform operations of a base station.

According to an embodiment, a method performed by a device for a near-real time radio access network intelligent controller, (near-RT RIC) of a telecommunication network, wherein the method comprise generating a control message for configuration related to at least one function of a radio unit (RU), and transmitting, to the RU, the control message via an interface between the near-RT RIC and the RU. The at least one function includes a function for controlling a power amplifier of the RU, a function for controlling an analog to digital controller (ADC), of the RU, or a function for controlling an antenna tilt and determining at least one beamforming weight.

For example, the near-real-time RIC is configured based on an xApp.

For example, the near-real-time RIC comprises artificial intelligence (AI) model. The AI model is deployed as or within an xApp instance.

For example, the AI model is arranged to be updated via an xApp update.

For example, the control message causes the RU to change at least one parameter related to the PA in case of that the control message includes the function for controlling the PA of the RU. The at least one parameter related to the PA includes a parameter for bias conditions, a parameter for an operating mode, a parameter for power levels of input and output, a parameter for gain control, a parameter for load impedance tuning, a parameter for temperature compensation, or a parameter for pre-distortion setting.

For example, the control message causes the RU to change at least one parameter related to the ADC in case of that the control message includes the function for controlling the ADC of the RU. The at least one parameter related to the ADC includes a parameter for quantization bits, a parameter for a sampling rate, a parameter for a dynamic range, a parameter for an input voltage range, a parameter for filtering setting, or a parameter for an operating mode.

For example, the method comprises receiving, from the RU, a response message to report completion of the configuration via the interface between the near-RT RIC and the RU.

According to an embodiment, a device for a near-real time radio access network intelligent controller, (near-RT RIC) of a telecommunication network, comprises memory comprising one or more media, storing instructions, and at least one processor comprising processing circuitry. The instructions, when executed by the at least one processor individually or collectively, cause the device to generate a control message for configuration related to at least one function of a radio unit (RU), and transmit, to the RU, the control message via an interface between the near-RT RIC and the RU. The at least one function includes a function for controlling a power amplifier of the RU, a function for controlling an analog to digital controller (ADC), of the RU, or a function for controlling an antenna tilt and determining at least one beamforming weight.

For example, the near-real-time RIC is configured based on an xApp.

For example, the near-real-time RIC comprises artificial intelligence (AI) model. The AI model is deployed as or within an xApp instance.

For example, the AI model is arranged to be updated via an xApp update.

For example, the control message causes the RU to change at least one parameter related to the PA in case of that the control message includes the function for controlling the PA of the RU. The at least one parameter related to the PA includes a parameter for bias conditions, a parameter for an operating mode, a parameter for power levels of input and output, a parameter for gain control, a parameter for load impedance tuning, a parameter for temperature compensation, or a parameter for pre-distortion setting.

For example, the control message causes the RU to change at least one parameter related to the ADC in case of that the control message includes the function for controlling the ADC of the RU. The at least one parameter related to the ADC includes a parameter for quantization bits, a parameter for a sampling rate, a parameter for a dynamic range, a parameter for an input voltage range, a parameter for filtering setting, or a parameter for an operating mode.

For example, the instructions, when executed by the at least one processor individually or collectively, cause the device to receive, from the RU, a response message to report completion of the configuration via the interface between the near-RT RIC and the RU.

According to an embodiment, a non-transitory computer readable storage medium storing one or more programs, wherein the one or more programs comprise instructions, when executed by at least one processor of a device for a near-real time radio access network intelligent controller, (near-RT RIC) of a telecommunication network, cause the device to generate a control message for configuration related to at least one function of a radio unit (RU), and transmit, to the RU, the control message via an interface between the near-RT RIC and the RU. The at least one function includes a function for controlling a power amplifier of the RU, a function for controlling an analog to digital controller (ADC), of the RU, or a function for controlling an antenna tilt and determining at least one beamforming weight.

For example, the near-real-time RIC is configured based on an xApp.

For example, the near-real-time RIC comprises artificial intelligence (AI) model. The AI model is deployed as or within an xApp instance.

For example, the AI model is arranged to be updated via an xApp update.

For example, the control message causes the RU to change at least one parameter related to the PA in case of that the control message includes the function for controlling the PA of the RU. The at least one parameter related to the PA includes a parameter for bias conditions, a parameter for an operating mode, a parameter for power levels of input and output, a parameter for gain control, a parameter for load impedance tuning, a parameter for temperature compensation, or a parameter for pre-distortion setting.

For example, the control message causes the RU to change at least one parameter related to the ADC in case of that the control message includes the function for controlling the ADC of the RU. The at least one parameter related to the ADC includes a parameter for quantization bits, a parameter for a sampling rate, a parameter for a dynamic range, a parameter for an input voltage range, a parameter for filtering setting, or a parameter for an operating mode.

At least some of the example embodiments described herein may be constructed, partially or wholly, using dedicated special-purpose hardware. Terms such as ‘component’, ‘module’ or ‘unit’ used herein may include, but are not limited to, a hardware device, such as circuitry in the form of discrete or integrated components, a Field Programmable Gate Array (FPGA) or Application Specific Integrated Circuit (ASIC), which performs certain tasks or provides the associated functionality. In some embodiments, the described elements may be configured to reside on a tangible, persistent, addressable storage medium and may be configured to execute on one or more processors. These functional elements may in some embodiments include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. Although the example embodiments have been described with reference to the components, modules and units discussed herein, such functional elements may be combined into fewer elements or separated into additional elements. Various combinations of optional features have been described herein, and it will be appreciated that described features may be combined in any suitable combination. In particular, the features of any one example embodiment may be combined with features of any other embodiment, as appropriate, except where such combinations are mutually exclusive. Throughout this specification, the term “comprising” or “comprises” means including the component(s) specified but not to the exclusion of the presence of others.

Attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The disclosure is not restricted to the details of the foregoing embodiment(s). The disclosure extends to any novel one, or any novel combination, of the features disclosed in this specification (including any accompanying claims, abstract and drawings), or to any novel one, or any novel combination, of the steps of any method or process so disclosed.

For one or more embodiments, at least one of the components set forth in one or more of the preceding figures may be configured to perform one or more operations, techniques, processes, and/or methods as set forth herein. For example, a processor (e.g., baseband processor) as described herein in connection with one or more of the preceding figures may be configured to operate in accordance with one or more of the examples set forth herein. For another example, circuitry associated with a UE, base station, network element, etc. as described above in connection with one or more of the preceding figures may be configured to operate in accordance with one or more of the examples set forth herein.

Any of the above-described embodiments may be combined with any other embodiment (or combination of embodiments), unless explicitly stated otherwise. The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

The methods according to various embodiments described in the claims and/or the specification of the disclosure may be implemented in hardware, software, or a combination of hardware and software.

When implemented by software, a computer-readable storage medium storing one or more programs (software modules) may be provided. One or more programs stored in such a computer-readable storage medium (e.g., non-transitory storage medium) are configured for execution by one or more processors in an electronic device. The one or more programs include instructions that cause the electronic device to execute the methods according to embodiments described in the claims or specification of the disclosure.

Such a program (e.g., software module, software) may be stored in a random-access memory, a non-volatile memory including a flash memory, a read only memory (ROM), an electrically erasable programmable read only memory (EEPROM), a magnetic disc storage device, a compact disc-ROM (CD-ROM), digital versatile discs (DVDs), other types of optical storage devices, or magnetic cassettes. Alternatively, it may be stored in a memory configured with a combination of some or all of the above. In addition, respective constituent memories may be provided in a multiple number.

Further, the program may be stored in an attachable storage device that can be accessed via a communication network, such as e.g., Internet, Intranet, local area network (LAN), wide area network (WAN), or storage area network (SAN), or a communication network configured with a combination thereof. Such a storage device may access an apparatus performing an embodiment of the disclosure through an external port. Further, a separate storage device on the communication network may be accessed to an apparatus performing an embodiment of the disclosure.

In the above-described specific embodiments of the disclosure, a component included therein may be expressed in a singular or plural form according to a proposed specific embodiment. However, such a singular or plural expression may be selected appropriately for the presented context for the convenience of description, and the disclosure is not limited to the singular form or the plural elements. Therefore, either an element expressed in the plural form may be formed of a singular element, or an element expressed in the singular form may be formed of plural elements.

Meanwhile, specific embodiments have been described in the detailed description of the disclosure, but it goes without saying that various modifications are possible without departing from the scope of the disclosure.

What is claimed is:

1. A method performed by a device for a near-real time radio access network intelligent controller, (near-RT RIC) of a telecommunication network,
wherein the method comprises:
generating a control message for configuration related to at least one function of a radio unit (RU), and
transmitting, to the RU, the control message via an interface between the near-RT RIC and the RU, and
wherein the at least one function includes a function for controlling a power amplifier of the RU, a function for controlling an analog to digital controller (ADC), of the RU, or a function for controlling an antenna tilt and determining at least one beamforming weight.

2. The method of claim 1, wherein the near-RT RIC is configured based on an xApp.

3. The method of claim 2,
wherein the near-RT RIC comprises artificial intelligence (AI) model, and
wherein the AI model is deployed as or within an xApp instance.

4. The method of claim 3, wherein the AI model is arranged to be updated via an xApp update.

5. The method of claim 1,
wherein the control message causes the RU to change at least one parameter related to the PA in case of that the control message includes the function for controlling the PA of the RU, and
wherein the at least one parameter related to the PA includes a parameter for bias conditions, a parameter for an operating mode, a parameter for power levels of input and output, a parameter for gain control, a parameter for load impedance tuning, a parameter for temperature compensation, or a parameter for pre-distortion setting.

6. The method of claim 1,
wherein the control message causes the RU to change at least one parameter related to the ADC in case of that the control message includes the function for controlling the ADC of the RU, and
wherein the at least one parameter related to the ADC includes a parameter for quantization bits, a parameter for a sampling rate, a parameter for a dynamic range, a parameter for an input voltage range, a parameter for filtering setting, or a parameter for an operating mode.

7. The method of claim 1, wherein the method comprises receiving, from the RU, a response message to report completion of the configuration via the interface between the near-RT RIC and the RU.

8. A device for a near-real time radio access network intelligent controller, (near-RT RIC) of a telecommunication network, the device comprising:
memory comprising one or more media, storing instructions; and
at least one processor comprising processing circuitry,
wherein the instructions, when executed by the at least one processor individually or collectively, cause the device to:
generate a control message for configuration related to at least one function of a radio unit (RU), and
transmit, to the RU, the control message via an interface between the near-RT RIC and the RU, and
wherein the at least one function includes a function for controlling a power amplifier of the RU, a function for controlling an analog to digital controller (ADC), of the RU, or a function for controlling an antenna tilt and determining at least one beamforming weight.

9. The device of claim 8, wherein the near-RT RIC is configured based on an xApp.

10. The device of claim 9,
wherein the near-RT RIC comprises artificial intelligence (AI) model, and
wherein the AI model is deployed as or within an xApp instance.

11. The device of claim 10, wherein the AI model is arranged to be updated via an xApp update.

12. The device of claim 8,
wherein the control message causes the RU to change at least one parameter related to the PA in case of that the control message includes the function for controlling the PA of the RU, and
wherein the at least one parameter related to the PA includes a parameter for bias conditions, a parameter for an operating mode, a parameter for power levels of input and output, a parameter for gain control, a parameter for load impedance tuning, a parameter for temperature compensation, or a parameter for pre-distortion setting.

13. The device of claim 8,
wherein the control message causes the RU to change at least one parameter related to the ADC in case of that the control message includes the function for controlling the ADC of the RU, and
wherein the at least one parameter related to the ADC includes a parameter for quantization bits, a parameter for a sampling rate, a parameter for a dynamic range, a parameter for an input voltage range, a parameter for filtering setting, or a parameter for an operating mode.

14. The device of claim 8, wherein the instructions, when executed by the at least one processor individually or collectively, cause the device to receive, from the RU, a response message to report completion of the configuration via the interface between the near-RT RIC and the RU.

15. A non-transitory computer readable storage medium storing one or more programs, wherein the one or more programs comprise instructions, when executed by at least one processor of a device for a near-real time radio access network intelligent controller, (near-RT RIC) of a telecommunication network, cause the device to:
generate a control message for configuration related to at least one function of a radio unit (RU); and
transmit, to the RU, the control message via an interface between the near-RT RIC and the RU,
wherein the at least one function includes a function for controlling a power amplifier of the RU, a function for controlling an analog to digital controller (ADC), of the RU, or a function for controlling an antenna tilt and determining at least one beamforming weight.

16. The non-transitory computer readable storage medium of claim 15,
wherein the near-RT RIC is configured based on an xApp.

17. The non-transitory computer readable storage medium of claim 16,
wherein the near-RT RIC comprises artificial intelligence (AI) model, and
wherein the AI model is deployed as or within an xApp instance.

18. The non-transitory computer readable storage medium of claim 17,
wherein the AI model is arranged to be updated via an xApp update.

19. The non-transitory computer readable storage medium of claim 15,
wherein the control message causes the RU to change at least one parameter related to the PA in case of that the control message includes the function for controlling the PA of the RU, and
wherein the at least one parameter related to the PA includes a parameter for bias conditions, a parameter for an operating mode, a parameter for power levels of input and output, a parameter for gain control, a parameter for load impedance tuning, a parameter for temperature compensation, or a parameter for pre-distortion setting.

20. The non-transitory computer readable storage medium of claim 15,
wherein the control message causes the RU to change at least one parameter related to the ADC in case of that the control message includes the function for controlling the ADC of the RU, and
wherein the at least one parameter related to the ADC includes a parameter for quantization bits, a parameter for a sampling rate, a parameter for a dynamic range, a parameter for an input voltage range, a parameter for filtering setting, or a parameter for an operating mode.
